(19) United States
(12) Patent Application Publication
(10) Pub. No.: US 2025/0329548 A1
(43) Pub. Date: Oct. 23, 2025

(54) METHOD OF MANUFACTURING SEMICONDUCTOR DEVICE, AND SEMICONDUCTOR DEVICE

(71) Applicant: RESONAC CORPORATION, Minato-ku, Tokyo (JP)

(72) Inventors: Keisuke NISHIDO, Chiyoda-ku, Tokyo (JP); Masaaki TAKEKOSHI, Chiyoda-ku, Tokyo (JP)

(21) Appl. No.: 18/861,879

(22) PCT Filed: Jun. 8, 2022
(86) PCT No.: PCT/JP2022/023129

§ 371 Date: Oct. 31, 2024

(51) Int. Cl. H01L 21/48; H01L 23/13; H01L 23/14; H01L 23/538; H05K 1/03; H05K 1/11; H05K 3/00

(52) U.S. Cl. CPC H01L 21/486; H01L 21/4857; H01L 23/13; H01L 23/145; H01L 23/5383; H01L 23/5386; H05K 1/0373; H05K 1/116; H05K 3/0055

(57) ABSTRACT

A method of manufacturing a semiconductor device of the present disclosure is one that includes a multilayer wiring in which wiring layers and insulating layers are alternately layered, wherein wiring layers that are adjacent to each other, in a layered direction, via an insulating layer are electrically connected to each other via a conductor present in a through hole provided in the insulating layer, and the multilayer wiring is formed by: providing, on a base, an insulating layer having a metal protective film on a surface thereof and containing inorganic fillers having an average maximum particle length B of from 1 μm to 100 μm; forming a through hole in the insulating layer; and subjecting, to a dry desmear treatment, the insulating layer in which the through hole is formed.

### TECHNICAL FIELD

The disclosure relates to a method of manufacturing a semiconductor device, and a semiconductor device.

### BACKGROUND ART

Mounting forms in which chips having different performances are mounted together in one package has been proposed for the purpose of achieving high density and high performance of a semiconductor package. In this respect, a high density inter-chip interconnection technology which is excellent in terms of cost is important (see, for example, Patent Document 1).

Non-Patent Document 1 and Non-Patent Document 2 describe aspects of a package-on-package (POP), in which a different package is layered on a package by flip-chip mounting to be connected to each other. This POP is an aspect widely adopted in smartphones, tablet terminals, and the like.

As other forms for mounting a plurality of chips at a high density, a packaging technology using an organic substrate including a high density wiring, a fan-out type packaging technology (FO-WLP: fanout-wafer level package) including a through mold via (TMV), a packaging technology using silicon or a glass interposer, a packaging technology using a through silicon via (TSV), a packaging technology in which a chip embedded in a substrate is used for inter-chip transmission, and the like have been proposed.

In particular, when semiconductor chips are mounted in a semiconductor wiring layer and the FO-WLP, a fine wiring layer for conducting the semiconductor chips to each other at a high density is required (see, for example, Patent Document 2).

### CITATION LIST

### Patent Documents

Patent Document 1: Japanese National-Phase Publication (JP-A) No 2012-529770 Patent Document 2: US 2011/0221071 A

### Non Patent Documents

Non-Patent Document 1: Jinseong Kim et al., “Application of Through Mold Via (TMV) as PoP Base Package”, Electronic Components and Technology Conference (ECTC), p. 1089-1092 (2008)

Non-Patent Document 2: Profile POP Solution with Embedded Wafer Level POP (eWLB-POP) Technology”, ECTC, p. 1250-1254 (2012)

### SUMMARY OF INVENTION

### Technical Problem

A wiring layer (semiconductor wiring layer) for mounting a plurality of semiconductor chips may be used for a build-up substrate, a wafer level package (WLP), a fan-out type PoP bottom package, and the like.

The wiring layer is configured as a multilayer wiring in which the wiring layers and insulating layers are alternately layered. As a metal which forms the wiring layer, for example, copper having high conductivity may be used in order to reduce cost and suppress an increase in wiring resistance. As a component which forms the insulating layer, a cured product of an epoxy resin composition having excellent balance among electrical properties, moisture resistance, heat resistance, mechanical properties, and the like may be used. The epoxy resin composition contains an inorganic filler for the purpose of, for example, improving the strength of the cured product and adjusting thermal expansion characteristics of the cured product. Since the strength of the cured product tends to be improved and the thermal expansion tends to be suppressed as the content of the inorganic filler increases, it may be desirable that the content of the inorganic filler in the epoxy resin composition is high. In this regard, as the content of the inorganic filler increases, the possibility that inorganic filler particles each having a large particle diameter are present tends to increase.

In order to secure conduction between the wiring layers, a via hole (through hole) may be provided in an insulating layer composed of the cured product of the epoxy resin composition containing the inorganic filler. Examples of a method of forming the through hole include laser processing. The inorganic filler contained in the epoxy resin composition may be exposed on a side surface of the through hole. An unevenness is generated on the side surface of the through hole due to the exposed inorganic filler. The unevenness of the side surface of the through hole may cause deterioration of the shape of the through hole. The deterioration of the through hole shape tends to be easily deteriorated as the possibility that the inorganic filler particles each having a large particle diameter are present increases.

The present disclosure has been made in view of the conventional circumstances, and an object of the disclosure is to provide a method of manufacturing a semiconductor device that can suppress the occurrence of the unevenness on the side surface of the through hole. Another object of the disclosure is to provide a semiconductor device including a highly reliable multilayer wiring.

### Solution to Problem

Specific means to attain the object as set forth below are as shown below.
<1>A method of manufacturing a semiconductor device comprising a multilayer wiring in which wiring layers and insulating layers are alternately layered,
   wherein wiring layers that are adjacent to each other, in a layered direction, via an insulating layer are electrically connected to each other via a conductor present in a through hole provided in the insulating layer, and
   the multilayer wiring is formed by:
      providing, on a base, an insulating layer having a metal protective film on a surface thereof and containing inorganic fillers having an average maximum particle length B of from 1 μm to 100 μm;
      forming a through hole in the insulating layer; and
      subjecting, to a dry desmear treatment, the insulating layer in which the through hole is formed.
<2>The method of manufacturing a semiconductor device according to <1>, wherein the dry desmear treatment is performed until an average height C of protrusions derived from the inorganic fillers on a side surface of the through hole and an average maximum particle length B of the inorganic fillers satisfy the following Relational Expression (I),

$$B > 2 C . \qquad ( I )$$

<3>The method of manufacturing a semiconductor device according to <1>or <2>,wherein the following Relational Expression (II) is satisfied, wherein A is an average diameter of the through hole,

$$A > 3 B . \qquad ( II )$$

<4>The method of manufacturing a semiconductor device according to any one of <1>to <3>, wherein the through hole is formed by at least one selected from the group consisting of laser processing and photolithography.
<5>The method of manufacturing a semiconductor device according to <4>, wherein the through hole is formed by removing, by the photolithography, a region corresponding to a portion at which the through hole is to be provided in the metal protective film, and then performing the laser processing on a portion from which the metal protective film is removed.
<6>The method of manufacturing a semiconductor device according to <4>, wherein the through hole is formed by performing the laser processing in a state in which the metal protective film is present on a surface of the insulating layer.
<7>The method of manufacturing a semiconductor device according to any one of <1>to <6>, wherein the insulating layer having the metal protective film on the surface thereof is provided on the base by:
   providing the insulating layer on the base;
   roughening the surface of the insulating layer; and
   disposing the metal protective film on the roughened surface of the insulating layer.
<8>The method of manufacturing a semiconductor device according to <7>, wherein the surface of the insulating layer is roughened by at least one selected from the group consisting of grinding, a chemical liquid treatment, and a plasma etching treatment.
<9>The method of manufacturing a semiconductor device according to <7>or <8>, wherein the metal protective film is formed by at least one selected from the group consisting of metal vapor deposition, electroless plating, and electrolytic plating.
<10>The method of manufacturing a semiconductor device according to any one of <7>to <9>, wherein a surface roughness Ra of the roughened insulating layer is from 0.1 μm to 2.0 μm.
<11>The method of manufacturing a semiconductor device according to any one of <1>to <10>, wherein the insulating layer is a cured product of an epoxy resin composition.
<12>The method of manufacturing a semiconductor device according to any one of <1>to <6>, wherein the insulating layer having the metal protective film on the surface thereof is provided on the base by: bringing, into contact with the base, an epoxy resin composition layer in an adhesive film, wherein the adhesive film comprises the epoxy resin composition layer and a metal foil in this order; and then curing the epoxy resin composition layer.
<13>The method of manufacturing a semiconductor device according to any one of <1>to <12>, further comprising forming a wiring layer on the insulating layer that has been treated by the dry desmear treatment.
<14>The method of manufacturing a semiconductor device according to <13>, wherein the wiring layer is formed after the metal protective film is removed from a surface of the insulating layer.
<15>The method of manufacturing a semiconductor device according to <13>, wherein the wiring layer is formed on the metal protective film.
<16>The method of manufacturing a semiconductor device according to <1>to <15>,further comprising performing, before the dry desmear treatment, at least one of a wet desmear treatment and a plasma ashing treatment.
<17>A semiconductor device, comprising:
   a semiconductor element; and
   a multilayer wiring in which wiring layers electrically connected to the semiconductor element, and insulating layers, are alternately layered,
   wherein:
   wiring layers that are adjacent to each other, in a layered direction, via an insulating layer are electrically connected to each other via a conductor present in a through hole provided in the insulating layer;
   the insulating layer comprises inorganic fillers having an average maximum particle length B of from 1 μm to 100 μm; and
   the following Relational Expressions (I) and (II) are satisfied, wherein C is an average height of protrusions derived from the inorganic fillers on a side surface of the through hole and A is an average diameter of the through hole,

$$B > 2 C , and \qquad ( I )$$

$$A > 3 B . \qquad ( II )$$

### Advantageous Effects of Invention

According to the disclosure, it is possible to provide a method of manufacturing a semiconductor device that can suppress occurrence of unevenness on a side surface of a through hole. Furthermore, according to the disclosure, a semiconductor device including a highly reliable multilayer wiring can be provided.

### BRIEF DESCRIPTION OF DRAWINGS

FIG. 1 is a cross-sectional view illustrating a state in which an insulating layer 14 containing inorganic fillers 12 having an average maximum particle length B of from 1 μm to 100 μm is provided on a semiconductor substrate 10.

FIG. 2 is a cross-sectional view illustrating a state in which a surface of the insulating layer 14 is roughened.

FIG. 3 is a cross-sectional view illustrating a state in which a metal protective film 16 is provided on a roughened surface of the insulating layer 14.

FIG. 4 is a view illustrating a state in which a region Q corresponding to a portion where a through hole is to be provided in the metal protective film 16 provided on the surface of the insulating layer 14 is partially removed.

FIG. 5 is a cross-sectional view illustrating a state in which a through hole 18 is provided on the surface of the insulating layer 14.

FIG. 6 is a cross-sectional view illustrating a state after a dry desmear treatment is performed on the insulating layer 14 in which the through hole 18 is formed.

### DESCRIPTION OF EMBODIMENTS

Embodiments for carrying out the invention will be described below in detail. However, the invention is not limited to the following embodiments. In the following embodiments, components (including elemental steps, etc.) thereof are not essential unless otherwise specified. The same applies to numerical values and ranges, which do not limit the invention.

In the numerical ranges described in a stepwise manner in the present disclosure, the upper limit value or the lower limit value described in one numerical range may be replaced with the upper limit value or the lower limit value of another numerical range described in a stepwise manner. Further, in the numerical ranges described in the present disclosure, the upper limit value or the lower limit value of the numerical ranges may be replaced with the values shown in the Examples.

In the present disclosure, each component may include plural substances corresponding to the component. In the case in which plural substances corresponding to a component are present in a composition, an amount or content of the component in the composition means the total amount or content of the plural substances present in the composition, unless otherwise specified.

In the present disclosure, each component may include plural kinds of particles corresponding to the component. In the case in which plural kinds of particles corresponding to a component are present in a composition, a particle size of the component means a value with respect to the mixture of the plural kinds of particles present in the composition, unless otherwise specified.

The term “layer” or “film” as used herein encompasses, when a region in which the layer or the film is present is observed, not only a case in which the layer or the film is formed over the entire observed region, but also a case in which the layer or the film is formed at only a part of the observed region.

The term “layered” as used herein means disposing layers on one another, in which two or more layers may be bonded with each other, or may be attachable to/detachable from one another.

In the present disclosure, a thickness of a layer or a film is a value obtained by measuring a thickness of the layer or the film as an object at 5 points and arithmetically averaging those values.

A thickness of a layer or a film can be measured using a micrometer or the like. In the present disclosure, in a case in which the thickness of the layer or the film can be measured directly, it is measured using a micrometer. On the other hand, in a case in which the thickness of one layer or the total thickness of a plurality of layers is measured, the thickness may be measured by observing the cross section of the object to be measured using an electron microscope.

### Method of Manufacturing Semiconductor Device

A method of manufacturing a semiconductor device of the disclosure relates to a method of manufacturing a semiconductor device including a multilayer wiring in which wiring layers and insulating layers are alternately layered, in which wiring layers that are adjacent to each other, in a layered direction, via an insulating layer are electrically connected to each other via a conductor present in a through hole provided in the insulating layer. In the method of manufacturing a semiconductor device of the disclosure, the multilayer wiring is formed by way of: providing, on a base, an insulating layer having a metal protective film on a surface thereof and containing inorganic fillers having an average maximum particle length B of from 1 μm to 100 μm; forming a through hole in the insulating layer; and subjecting, to a dry desmear treatment, the insulating layer in which the through hole is formed.

According to the method of manufacturing a semiconductor device of the disclosure, it is possible to suppress the occurrence of the unevenness on the side surface of the through hole. The reason is not clear, but is presumed as follows.

When the through hole is provided in the insulating layer by a method such as laser processing, the inorganic filler may be exposed on the side surface of the through hole. In particular, when the through hole is provided in the insulating layer by laser processing, a resin component which forms the insulating layer is removed by laser irradiation, but the inorganic filler is hardly removed, and accordingly the inorganic filler is easily exposed on the side surface of the through hole. In order to remove the inorganic filler exposed on the side surface of the through hole, the dry desmear treatment is effective. However, since the dry desmear treatment removes not only the inorganic filler but also the resin component which forms the insulating layer, the surface of the insulating layer is roughened by the dry desmear treatment, and the insulating properties of the insulating layer may be deteriorated.

In the disclosure, the insulating layer is subject to the dry desmear treatment in a state in which the insulating layer has the metal protective film on its surface thereof. Since the metal protective film is less likely to be eroded by the dry desmear treatment, the metal protective film functions as a protective film of the insulating layer against the dry desmear treatment. Therefore, it is possible to remove the inorganic filler exposed on the side surface of the through hole while suppressing the occurrence of roughness on the surface of the insulating layer. It is presumed that, as a result thereof, the occurrence of the unevenness on the side surface of the through hole can be suppressed.

In the disclosure, a maximum particle length B of the inorganic fillers contained in the insulating layer is from 1 μm to 100 μm. When the maximum particle length B of the inorganic fillers contained in the insulating layer is from 1 μm to 100 μm, the strength of the insulating layer tends to be improved and the thermal expansion tends to be suppressed, but the unevenness derived from the inorganic fillers on the side surface of the through hole tend to be large, and the shape of the through hole tends to be deteriorated. The method of manufacturing a semiconductor device of the disclosure is also effective in forming the through hole in the insulating layer containing the inorganic fillers each having a large particle diameter.

Hereinafter, the method of manufacturing a semiconductor device of the disclosure will be described in detail.

In the following method of manufacturing, a case will be described in which the insulating layer having the metal protective film on the surface thereof is provided on the base by providing the insulating layer on the base, roughening the surface of the insulating layer, and disposing the metal protective film on a roughened surface of the insulating layer. However, the method of providing, on the base, the insulating layer having the metal protective film on the surface is not limited by the above-described method. In the following method of manufacturing, a case will be described in which the through hole is provided by removing, by photolithography, a region corresponding to a portion where the through hole is to be provided in the metal protective film and then performing laser processing on a portion where the metal protective film is removed. However, the method of forming the through hole is not limited to the above-described method. Note that sizes of members in the drawings are conceptual, and relative relationships between the sizes of the members are not limited thereto. Members having substantially the same functions are denoted by the same reference numerals throughout the drawings, and redundant description may be omitted.

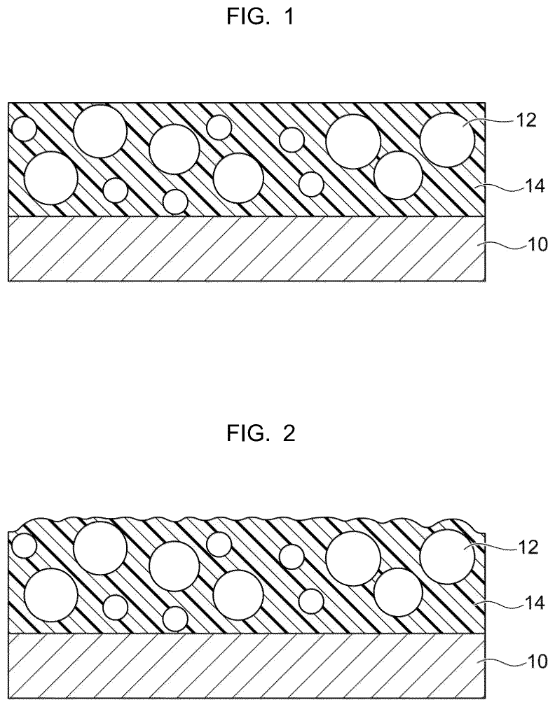

FIG. 1 is a cross-sectional view illustrating a state in which an insulating layer 14 containing inorganic fillers 12 having an average maximum particle length B of from 1 μm to 100 μm is provided on a semiconductor substrate 10 as an example of a base. The insulating layer 14 is, for example, a cured product of an epoxy resin composition. Examples of the base include, in addition to a semiconductor substrate such as a silicon substrate, an FO-WLP, a wafer level chip scale package (WLCSP), a fan in wafer level package (FI-WLP), a glass substrate, a glass epoxy substrate such as an FR-4 substrate, a polyester substrate, a polyimide substrate, a BT resin substrate, and a polyphenylene ether substrate.

An average thickness of the insulating layer 14 is preferably 5 μm or more, more preferably 10 μm or more, and still more preferably 20 μm or more from the viewpoint of securing insulating properties. The average thickness of the insulating layer 14 is preferably 200 μm or less, more preferably 100 μm or less, still more preferably 50 μm or less from the viewpoint of reducing the thickness of the semiconductor device. The average thickness of the insulating layer 14 is preferably from 5 μm to 200 μm, more preferably from 10 μm to 100 μm, and still more preferably from 20 μm to 50 μm.

The composition of the epoxy resin composition which forms the insulating layer 14 is not particularly limited, and an epoxy resin composition in a solid state at 25° C. is preferable.

The epoxy resin composition contains, for example, an epoxy resin, a curing agent, and an inorganic filler, and may contain other components as necessary.

The epoxy resin composition of the disclosure contains the epoxy resin.

The type of the epoxy resin is not particularly limited as long as the epoxy resin has two or more epoxy groups in one molecule.

Specifically, examples thereof include: a novolac type epoxy resin (phenol novolac type epoxy resin, orthocresol novolac type epoxy resin, etc.), that is an epoxidized novolac resin obtained by condensing or co-condensing at least one phenolic compound selected from the group consisting of a phenol compound such as phenol, cresol, xylenol, resorcin, catechol, bisphenol A, and bisphenol F and a naphthol compound such as α-naphthol, β-naphthol, and dihydroxynaphthalene and an aliphatic aldehyde compound such as formaldehyde, acetaldehyde, and propionaldehyde under the presence of an acidic catalyst; a triphenylmethane type epoxy resin obtained by epoxidizing a triphenylmethane type phenol resin obtained by condensing or co-condensing the phenolic compound with an aromatic aldehyde compound such as benzaldehyde or salicylaldehyde under the presence of an acidic catalyst; a copolymerized epoxy resin obtained by epoxidizing a novolak resin obtained by co-condensing the phenol compound and the naphthol compound and an aldehyde compound under the presence of an acidic catalyst; a diphenylmethane epoxy resin that is diglycidyl ether such as bisphenol A or bisphenol F; a biphenyl epoxy resin that is diglycidyl ether of alkyl-substituted or unsubstituted biphenol; a stilbene type epoxy resin that is diglycidyl ether of a stilbene-based phenol compound; a sulfur atom-containing type epoxy resin that is diglycidyl ether such as bisphenol S; an epoxy resin that is glycidyl ether of alcohols such as butanediol, polyethylene glycol, and polypropylene glycol; a glycidyl ester type epoxy resin that is glycidyl ester of a polyvalent carboxylic acid compound such as phthalic acid, isophthalic acid, or tetrahydrophthalic acid; a glycidylamine type epoxy resin obtained by substituting active hydrogen bonded to a nitrogen atom of aniline, diaminodiphenylmethane, isocyanuric acid, or the like with a glycidyl group; a dicyclopentadiene type epoxy resin obtained by epoxidizing a co-condensation resin between dicyclopentadiene and a phenol compound; an alicyclic epoxy resin obtained by epoxidizing an olefin bond in a molecule, such as vinylcyclohexene diepoxide, 3,4-epoxycyclohexylmethyl-3,4-epoxycyclohexanecarboxylate, and 2-(3,4-epoxy) cyclohexyl-5,5-spiro (3,4-epoxy) cyclohexane-m-dioxane; a para-xylylene-modified epoxy resin that is glycidyl ether of a para-xylylene-modified phenol resin; a meta-xylylene-modified epoxy resin that is glycidyl ether of a meta-xylylene-modified phenol resin; a terpene-modified epoxy resin that is glycidyl ether of a terpene-modified phenol resin; a dicyclopentadiene-modified epoxy resin that is a glycidyl ether of a dicyclopentadiene-modified phenol resin; a cyclopentadiene-modified epoxy resin that is glycidyl ether of a cyclopentadiene-modified phenol resin; a polycyclic aromatic ring-modified epoxy resin that is glycidyl ether of a polycyclic aromatic ring-modified phenol resin; a naphthalene type epoxy resin that is glycidyl ether of a naphthalene ring-containing phenol resin; a halogenated phenol novolac type epoxy resin; a hydroquinone type epoxy resin; a trimethylolpropane type epoxy resin; a linear aliphatic epoxy resin obtained by oxidizing olefin bond with peracid such as peracetic acid; and an aralkyl type epoxy resin obtained by epoxidizing an aralkyl type phenol resin such as a phenol aralkyl resin or a naphthol aralkyl resin. Furthermore, examples of the epoxy resin include an epoxidized product of a silicone resin and an aminophenol type epoxy resin that is glycidyl ether of aminophenol. These epoxy resins may be used singly, or in combination of two or more kinds thereof.

The epoxy resin composition of the disclosure contains a curing agent.

The type of the curing agent is not particularly limited, and is not particularly limited as long as the curing agent is a compound that causes a curing reaction with the epoxy resin to be used in combination. Examples of the curing agent used in combination with the epoxy resin include a phenol-based curing agent, an amine-based curing agent, an acid anhydride-based curing agent, a polymercaptan-based curing agent, a polyaminoamide-based curing agent, an isocyanate-based curing agent, and a blocked isocyanate-based curing agent. These curing agents may be used singly, or in combination of two or more kinds thereof. The curing agent may be a solid or a liquid under a normal temperature and a normal pressure (for example, at 25° C. and under an atmospheric pressure), and is preferably a solid.

The curing agent is preferably the phenol-based curing agent or the amine-based curing agent from the viewpoint of heat resistance.

Examples of the phenol-based curing agent include a phenol resin and a polyhydric phenol compound each including two or more phenolic hydroxyl groups in one molecule. Specifically, examples thereof include a polyhydric phenol compound such as resorcin, catechol, bisphenol A, bisphenol F, and substituted or unsubstituted biphenol; a novolac type phenol resin obtained by condensing or co-condensing at least one phenolic compound selected from the group consisting of a phenol compound such as phenol, cresol, xylenol, resorcin, catechol, bisphenol A, bisphenol F, phenylphenol, and aminophenol and a naphthol compound such as α-naphthol, β-naphthol, and dihydroxynaphthalene and an aldehyde compound such as formaldehyde, acetaldehyde, and propionaldehyde under the presence of an acidic catalyst; an aralkyl type phenol resin such as a phenol aralkyl resin or a naphthol aralkyl resin synthesized from the phenolic compound and dimethoxyparaxylene, bis (methoxymethyl) biphenyl, or the like; a paraxylylene-modified phenol resin; a metaxylylene-modified phenol resin; a melamine-modified phenol resin; a terpene-modified phenol resin; a dicyclopentadiene type phenol resin and a dicyclopentadiene type naphthol resin synthesized by copolymerization from the phenolic compound and dicyclopentadiene; a cyclopentadiene-modified phenol resin; a polycyclic aromatic ring-modified phenol resin; a biphenyl type phenol resin; a triphenylmethane type phenol resin obtained by condensing or co-condensing the phenolic compound and an aromatic aldehyde compound such as benzaldehyde or salicylaldehyde under the presence of an acidic catalyst; and a phenol resin obtained by copolymerizing two or more of these. Furthermore, examples of the phenol-based curing agent also include a monohydric phenol compound including one phenolic hydroxyl group in one molecule. These phenolic curing agents may be used singly, or in combination of two or more kinds thereof.

Specific examples of the amine-based curing agent include an aliphatic amine compound such as diethylenetriamine, triethylenetetramine, n-propylamine, 2-hydroxyethylaminopropylamine, cyclohexylamine, and 4,4′-diamino-dicyclohexylmethane; an aromatic amine compound such as diethyltoluenediamine, 3,3′-diethyl-4,4′-diaminodiphenylmethane, dimethylthiotoluenediamine, and 2-methylaniline; and an imidazoline compound such as imidazoline, 2-methylimidazoline, and 2-ethylimidazoline. Among them, from the viewpoint of storage stability, aromatic amine compound is preferable, and diethyltoluenediamine, 3,3′-diethyl-4,4′-diaminodiphenylmethane, and dimethylthiotoluenediamine are more preferable.

A functional group equivalent (, which is hydroxyl group equivalent when the curing agent is a phenol curing agent, and which is active hydrogen equivalent when the curing agent is an amine-based curing agent,) of the curing agent is not particularly limited. From the viewpoint of balance among various characteristics such as moldability, heat resistance, and electrical reliability, the functional group equivalent is preferably from 10 g/eq to 1000 g/eq, and more preferably from 30 g/eq to 500 g/eq.

The hydroxyl group equivalent in the case of the phenol curing agent refers to a value calculated based on a hydroxyl value measured in accordance with JIS K0070:1992. The active hydrogen equivalent in the case of the amine-based curing agent refers to a value calculated based on an amine value measured in accordance with JIS K7237:1995.

In the epoxy resin composition, when the curing agent contains the phenol-based curing agent, the epoxy resin composition may contain or need not contain a curing accelerator.

A type of the curing accelerator is not particularly limited, and can be selected according to the type of the epoxy resin, desired characteristics of the epoxy resin composition, and the like.

The curing accelerator is not particularly limited. The curing accelerator may be, for example, at least one selected from the group consisting of an amine-based curing accelerator, an imidazole-based curing accelerator, a urea-based curing accelerator, and a phosphorus-based curing accelerator.

Examples of the amine-based curing accelerator include 1,8-diazabicyclo[5.4.0]-7-undecene and 1,5-diazabicyclo[4.3.0]-5-nonene.

Examples of the imidazole-based curing accelerator include 2-phenyl-4-methylimidazole, 2-ethyl-4-methylimidazole, 1-cyanoethyl-2-ethyl-4 methylimidazole, 2-methylimidazole, 1-cyanoethyl-2-phenylimidazole, 1-cyanoethyl-2-phenylimidazolium trimellitate, and 2-phenyl-4 methyl-5-hydroxymethylimidazole.

Examples of the urea-based curing accelerator include 3-phenyl-1,1-dimethylurea.

Examples of the phosphorus-based curing accelerator include triphenylphosphine and an addition reaction product thereof, diphenyl (p-tolyl) phosphine, tris (alkylphenyl) phosphine, tris (alkoxyphenyl) phosphine, tris (alkylalkoxyphenyl) phosphine, tris (dialkylphenyl) phosphine, tris (trialkylphenyl) phosphine, tris (tetraalkylphenyl) phosphine, tris (dialkoxyphenyl) phosphine, tris (trialkoxyphenyl) phosphine, tris (tetraalkoxyphenyl) phosphine, trialkylphosphine, dialkylarylphosphine, alkyldiarylphosphine, (4-hydroxyphenyl) diphenylphosphine, bis (4-hydroxyphenyl) phenylphosphine, and tris (4-hydroxyphenyl) phosphine.

When the epoxy resin composition contains the curing accelerator, the content of the curing accelerator is preferably from 0.1% by mass to 8% by mass, more preferably from 0.3% by mass to 6% by mass, and still more preferably from 0.5% by mass to 5% by mass with respect to the total amount of the epoxy resin and the curing agent.

The epoxy resin composition of the disclosure contains an inorganic filler.

The type of the inorganic filler is not particularly limited. Specific examples thereof include an inorganic material such as silica such as spherical silica and crystalline silica, glass, alumina, calcium carbonate, zirconium silicate, calcium silicate, silicon nitride, aluminum nitride, boron nitride, aluminum nitride, boehmite, beryllia, magnesium oxide, zirconia, zircon, fosterite, steatite, spinel, mullite, titania, talc, clay, mica, and titanate. An inorganic filler having a flame retardant effect may be used. Examples of the inorganic filler having the flame retardant effect include an aluminum hydroxide, a magnesium hydroxide, and a composite metal hydroxide such as a composite hydroxide of magnesium and zinc, and zinc borate. Among them, spherical silica is preferable from the viewpoint of reducing the linear expansion coefficient, and alumina is preferable from the viewpoint of high thermal conductivity. The inorganic filler may be used singly, or in combination of two or more kinds thereof. Examples of a state of the inorganic filler include a powder form, beads obtained by spheroidizing a powder, and fibers.

The average particle size of the inorganic fillers is not particularly limited. For example, the volume average particle diameter is preferably 30 μm or less, more preferably from 0.1 μm to 30 μm, still more preferably from 0.2 μm to 25 μm, and particularly preferably from 0.5 μm to 20 μm. When the volume average particle diameter is 30 μm or less, the filling property tends to be improved. When the volume average particle diameter is 0.1 μm or more, an increase in viscosity of the epoxy resin composition tends to be further suppressed.

The volume average particle diameter of the inorganic filler can be measured as a volume average particle diameter (D50) by a laser diffraction scattering particle size distribution measuring device.

From the viewpoint of fluidity of the epoxy resin composition, the particle shape of the inorganic filler is preferably spherical rather than rectangular, and the particle size distribution of the inorganic fillers is preferably one that is distributed in a wide range.

The content of the inorganic filler in the epoxy resin composition is not particularly limited. From the viewpoint of fluidity and strength, the content is preferably 60% by volume or more, more preferably from 60% by volume to 90% by volume, and still more preferably from 62% by volume to 88% by volume, with respect to the total solid content of the epoxy resin composition. When the content of the inorganic filler is 60% by volume or more of the total solid content of the epoxy resin composition, the characteristics such as the thermal expansion coefficient, thermal conductivity, and elastic modulus of the cured product tend to be further improved. When the content of the inorganic filler is 90% by volume or less of the total solid content of the epoxy resin composition, an increase in the viscosity of the epoxy resin composition is suppressed, and the fluidity tends to be further improved, leading to more favorable moldability.

### Colorant

The epoxy resin composition of the disclosure may contain a colorant.

Examples of the colorant include known colorants such as carbon black, a black titanium oxide, an organic dye, an organic pigment, red lead, and a red iron oxide. The content of the colorant can be appropriately selected according to the purpose or the like. The colorant may be used singly, or in combination of two or more kinds thereof.

When the epoxy resin composition contains the colorant, the content thereof is preferably from 0.01% by mass to 5% by mass, and more preferably from 0.05% by mass to 3% by mass.

### Ion Exchanger

The epoxy resin composition of the disclosure may contain an ion exchanger.

In particular, from the viewpoint of improving the moisture resistance and the high temperature leaving characteristics of the semiconductor device, it is preferable to contain the ion exchanger. The ion exchanger is not particularly limited, and conventionally known ion exchangers can be used. Specific examples thereof include a hydrotalcite compound and a hydrous oxide of at least one element selected from the group consisting of magnesium, aluminum, titanium, zirconium, and bismuth. The ion exchanger may be used singly, or in combination of two or more kinds thereof. Among them, hydrotalcite represented by the following Formula (A) is preferable.

$${Mg}_{( 1 - X )} {{Al}_{X} ( OH )}_{2} {( {CO}_{3} )}_{X / 2} \cdot m {H}_{2} O \qquad ( A )$$

(0<X≤0.5, m is a positive number)

When the epoxy resin composition contains the ion exchanger, the content thereof is not particularly limited as long as the content is an amount sufficient to trap ions such as halogen ions. For example, the content is preferably from 0.1 parts by mass to 30 parts by mass, and more preferably from 1 part by mass to 5 parts by mass with respect to 100 parts by mass of the epoxy resin.

### Release Agent

The epoxy resin composition of the disclosure may contain a release agent from the viewpoint of obtaining favorable releasability. The release agent is not particularly limited, and conventionally known release agents can be used. Specific examples thereof include a higher fatty acid such as a carnauba wax, a montanic acid and a stearic acid, a higher fatty acid metal salt, an ester-based wax such as montanic acid ester, and a polyolefin-based wax such as oxidized polyethylene and non-oxidized polyethylene. The release agent may be used singly, or in combination of two or more kinds thereof.

When the epoxy resin composition contains the release agent, the content thereof is preferably from 0.01 parts by mass to 15 parts by mass, and more preferably from 0.1 parts by mass to 10 parts by mass with respect to 100 parts by mass of the epoxy resin. When the amount of the release agent is 0.01 parts by mass or more with respect to 100 parts by mass of the epoxy resin, releasability tends to be sufficiently obtained. When the amount of the release agent is 15 parts by mass or less with respect to 100 parts by mass of the epoxy resin, more favorable adhesiveness tends to be obtained.

### Flame Retardant

The epoxy resin composition of the disclosure may contain a flame retardant. The flame retardant is not particularly limited, and conventionally known flame retardants can be used. Specific examples thereof include organic or inorganic compounds containing a halogen atom, an antimony atom, a nitrogen atom, or a phosphorus atom, and metal hydroxides. The flame retardant may be used singly, or in combination of two or more kinds thereof.

When the epoxy resin composition contains the flame retardant, the content thereof is not particularly limited as long as content is an amount sufficient to obtain a desired flame retardant effect. For example, the content is preferably from 1 part by mass to 30 parts by mass, and more preferably from 2 part by mass to 20 parts by mass with respect to 100 parts by mass of the epoxy resin.

### Stress Relaxing Agent

The epoxy resin composition of the disclosure may contain a stress relaxing agent such as silicone rubber particles. When the epoxy resin composition contains the stress relaxing agent, warpage deformation of the insulating layer and occurrence of cracks in the insulating layer can be further reduced. Examples of the stress relaxing agent include commonly used known stress relaxing agents (flexing agents). Specific examples thereof include a thermoplastic elastomer such as a silicone-based, styrene-based, olefin-based, urethane-based, polyester-based, polyether-based, polyamide-based, or polybutadiene-based elastomer which may be epoxy-modified, rubber particles such as particles of natural rubber (NR), acrylonitrile-butadiene rubber (NBR), acrylic rubber, or urethane rubber, or silicone powder, rubber particles having a core-shell structure such as those of methyl methacrylate-styrene-butadiene copolymer (MBS), methyl methacrylate-silicone copolymer, or methyl methacrylate-butyl acrylate copolymer, and indene-containing copolymer that is a copolymer resin of indenes such as indene and alkylindene, styrenes such as styrene and alkylstyrene, and other monomers used as necessary. The stress relaxing agent may be used singly, or in combination of two or more kinds thereof.

When the epoxy resin composition contains the stress relaxing agent, the content thereof is preferably from 0.1 parts by mass to 30 parts by mass, and more preferably from 1 part by mass to 25 parts by mass with respect to 100 parts by mass of the epoxy resin.

### Coupling Agent

The epoxy resin composition of the disclosure may contain a coupling agent. The type of the coupling agent is not particularly limited, and a known coupling agents can be used. Examples of the coupling agent include a silane coupling agent and a titanium coupling agent. The coupling agent may be used singly, or in combination of two or more kinds thereof.

When the epoxy resin composition contains the coupling agent, the content of the coupling agent is preferably from 0.001 parts by mass to 10 parts by mass, more preferably from 0.01 parts by mass to 8 parts by mass, and still more preferably from 0.05 parts by mass to 5 parts by mass with respect to 100 parts by mass of the inorganic filler from the viewpoint of adhesion of the interface between the epoxy resin and the inorganic filler.

The method of applying the epoxy resin composition onto the semiconductor substrate 10 is not particularly limited. In one example, a solvent may be added to the epoxy resin composition to prepare a liquid epoxy resin composition, and the liquid epoxy resin composition may be applied onto the semiconductor substrate 10 by using a bar coating method, a spin coating method, or the like and dried. In another example, an adhesive film which includes a support and an epoxy resin composition layer provided on the support may be layered on the semiconductor substrate 10 such that the epoxy resin composition layer is in contact with the semiconductor substrate 10.

The support is not particularly limited in terms of shape and material as long as the epoxy resin composition layer can be formed on the support, and a metal foil or a resin film is preferable. Examples of the metal foil include a copper foil, an aluminum foil, and a nickel foil. Examples of the resin film that can be used include plastic films such as a polyethylene terephthalate film, a polyimide film, a polyethylene film, a polypropylene film, a polytetrafluoroethylene film, a polymethylpentene film, a polyamideimide film, a polyetherimide film, a polyethersulfone film, a wholly aromatic polyester film, a polytetrafluoroethylene film, an ethylene-tetrafluoroethylene copolymer film, a tetrafluoroethylene-hexafluoropropylene copolymer film, and a tetrafluoroethylene-perfluoroalkylvinyl ether copolymer film, and each of these plastic films can also be used after a surface thereof is subject to a release treatment.

In another way, the epoxy resin composition may be applied onto the support and dried to form the epoxy resin composition layer, and then a protective film may be layered on the epoxy resin composition layer. By providing the protective film on the epoxy resin composition layer, the handleability of the adhesive film is improved. As the protective film, the same one as the support can be used. Among them, when the adhesive film is wound by a roll coating method or the like with high productivity, a polyolefin film such as a polyethylene film or a polypropylene film, which is more flexible than a polyethylene terephthalate film, is suitable as the protective film.

As a method of applying the epoxy resin composition to the support, a known method can be used, and a dip coating method, a flow coating method, a spin coating method, a curtain coating method, a knife coating method, a roll coating method, a wire bar coating method, a doctor blade coating method, a comma blade method, a spray coating method, an ultrasonic coating method, an inkjet coating method, a die coating method, a gravure coating method, a screen printing method, a trowel coating method, a brush coating method, a sponge coating method, and the like can be applied. Among them, the comma blade method or the roll coating method of a kiss touch, which provides high productivity and enables precision coating with a uniform thickness, is suitable.

A temperature to be used for drying the epoxy resin composition applied to the support is not particularly limited. When the epoxy resin composition is formed in a varnish-like state by dissolving or dispersing each component in an organic solvent, the drying is preferably performed at a temperature lower than the boiling point of the used organic solvent by from 10° C. to 50° C. from the viewpoint of suppressing generation of bubbles in the adhesive film due to foaming of the organic solvent during drying. In this sense, the drying temperature is preferably lower than the boiling point of the organic solvent by from 15° C. to 45° C., and more preferably lower by from 20° C. to 40° C.

Layering of the semiconductor substrate 10 and the adhesive film may be performed by a vacuum lamination method. In the vacuum lamination method, a thermal crimping temperature is preferably from 60°° C. to 160° C., and more preferably from 80° C. to 140° C. A crimping pressure is preferably from 0.1 MPa to 2 MPa, more preferably from 0.3 MPa to 1.5 MPa. A crimping time is preferably from 10 seconds to 500 seconds, and more preferably from 20 seconds to 400 seconds. The layering is performed preferably under reduced pressure conditions of a pressure of 30 hPa or less.

Conditions of curing of the epoxy resin composition layer are not particularly limited. The temperature of a heat treatment is preferably from 120° C. to 200° C., more preferably from 130° C. to 180° C., and still more preferably from 140°° C. to 170° C. A heat treatment time is preferably from 5 minutes to 3 hours, and more preferably from 10 minutes to 2 hours.

The insulating layer 14 is formed on the semiconductor substrate 10 by curing the epoxy resin composition layer.

As another method of forming the insulating layer 14 on the semiconductor substrate 10, a transfer molding method, an injection molding method, a compression molding method, or the like, which is exemplified as a method of sealing an electronic component device by using the epoxy resin composition, may be used.

FIG. 2 is a cross-sectional view illustrating a state in which a surface of the insulating layer 14 is roughened. A roughening method of the insulating layer 14 is not particularly limited, and may be a dry method or a wet method.

Examples of a dry roughening method include mechanical polishing such as buffing and sandblasting, grinding using a grindstone or the like, a plasma etching treatment using a CF₄ gas, an SF₆ gas or the like, and the like. Examples of a wet roughening method include a chemical liquid treatment using an oxidant such as permanganate, dichromate, ozone, hydrogen peroxide/sulfuric acid, and nitric acid, a strong base, a resin swelling solvent, and the like. The wet roughening method may be a wet desmear treatment described later.

The surface of the insulating layer 14 is preferably roughened by at least one selected from the group consisting of grinding, a chemical liquid treatment, and a plasma etching treatment.

Surface roughness Ra of the roughened insulating layer 14 is preferably from 0.1 μm to 2.0 μm, more preferably from 0.2 μm to 0.5 μm, still more preferably from 0.2 μm to 0.4 μm, and particularly preferably from 0.2 μm to 0.3 μm.

In the disclosure, the surface roughness Ra refers to a value measured in accordance with JIS B0601:2013.

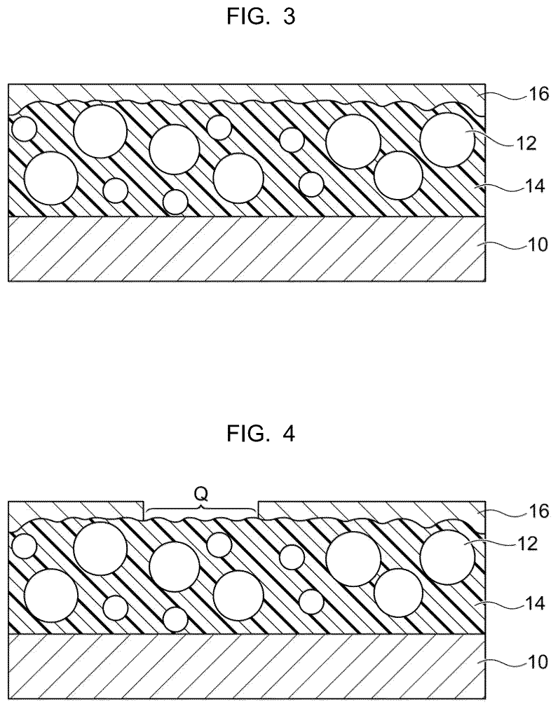

FIG. 3 is a cross-sectional view illustrating a state in which a metal protective film 16 is provided on a roughened surface of the insulating layer 14. A method of forming the metal protective film 16 on the surface of the insulating layer 14 is not particularly limited, and may be a dry method or a wet method, and is appropriately selected depending on the type of metal which forms the metal protective film 16.

Examples of the metal which forms the metal protective film 16 include copper, a copper alloy, and titanium.

Examples of a metal vapor deposition method by the dry method include a vacuum vapor deposition method and a sputtering method as a physical method, and include a chemical vapor deposition method (CVD) as a chemical method.

The vacuum vapor deposition method is a method of forming a thin film on an object by heating and evaporating a film-forming material by resistance heating or electron gun irradiation.

The sputtering method is a method of applying a voltage between an anode and a cathode to ionize an inert gas such as Ar, causing the inert gas ions to collide with a target material disposed on the cathode side to scatter the target material, and layering the scattered target material on the object disposed on the anode side.

Examples of the wet method include electroless plating and electrolytic plating. The electroless plating and the electrolytic plating may be employed in combination.

The metal protective film is preferably formed by at least one selected from the group consisting of the metal vapor deposition, the electroless plating, and the electrolytic plating.

The metal protective film may be composed of one layer or two or more layers. When the metal protective film is composed of two or more layers, the types of metals contained in the layers may be the same or different.

The average thickness of the metal protective film 16 is preferably from 0.1 μm to 2.0 μm, more preferably from 0.1 μm to 1.0 μm, and still more preferably from 0.1 μm to 0.5 μm. When the metal protective film 16 is composed of two or more layers, the average thickness of the metal protective film 16 refers to the average thickness of the entire metal protective film 16 composed of the two or more layers.

FIG. 4 is a view illustrating a state in which the metal protective film 16 of a region (region Q) corresponding to a portion where the through hole is to be provided in the metal protective film 16 provided on the surface of the insulating layer 14 is partially removed.

A method of partially removing the metal protective film 16 is not particularly limited, and the metal protective film 16 can be partially removed by photolithography (lamination of dry film resist (DFR), ultraviolet curing, development of the DFR, etching of the metal protective film 16, and peeling of the DFR), which is a well-known technique.

The shape of the region Q when observed from the thickness direction of the insulating layer 14 may be matched with the shape of the through hole to be formed in the insulating layer 14, and the shapes of the through hole and the region Q are generally circular.

The ratio (Q/A) of an average diameter Q of the regions Q to an average diameter A of the through hole to be formed in the insulating layer 14 when observed from the thickness direction of the insulating layer 14 is preferably from 1.0 to 1.5, more preferably from 1.0 to 1.2, and still more preferably from 1.0 to 1.1.

In the disclosure, a diameter of the through hole refers to a circle equivalent diameter at the narrowest portion of the through hole when the through hole is observed from the thickness direction of the insulating layer 14. In the disclosure, the average diameter A of the through hole refers to an arithmetic average of circle equivalent diameters of five through hole. An average diameter Q of the regions Q refers to an arithmetic average of circle equivalent diameters of five regions Q.

For example, when the cross-sectional shape of the through hole is a tapered shape as illustrated in FIG. 6 and the like described later, the average diameter A of the through hole refers to an arithmetic average of diameters of bottom portions of the through hole as illustrated in FIG. 6 described later.

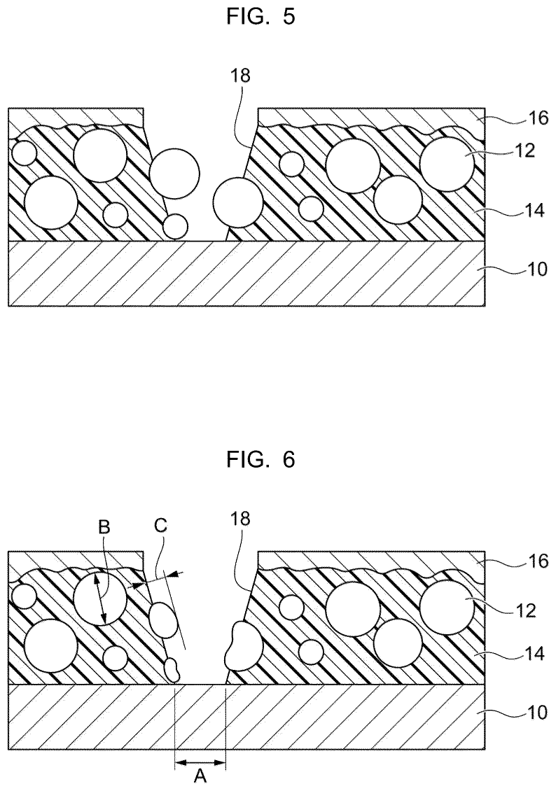

FIG. 5 is a cross-sectional view illustrating a state in which a through hole 18 is provided on the surface of the insulating layer 14. Formation of the through hole 18 in the insulating layer 14 can be performed by laser processing or the like. Among them, the laser processing is preferable from the viewpoint of suppressing a damage of the wiring.

When the through hole 18 is formed by the laser processing, examples of the laser to be used include a carbon dioxide laser (CO₂ laser), a UV laser, a YAG laser, and an excimer laser.

A wavelength, the number of pulses, a pulse width, an output, and the like of the laser are selected in accordance with the diameter of the through hole 18.

In the method of manufacturing a semiconductor device of the disclosure, it is preferable that A and B satisfy the following Relational Expression (II) where A is the average of the diameter of the through hole 18. When A and B satisfy the following Relational Expression (II), the through hole 18 is less likely to be blocked by the inorganic fillers 12 exposed on the side surface, the bonding strength of a conductor formed in the through hole to the insulating layer is secured, and the reliability of the multilayer wiring tends to be improved. The ratio (A/B) of the average diameter A to the average maximum particle length B is preferably from 3.1 to 10.0, more preferably from 3.5 to 8.0, and still more preferably from 4.0 to 6.0.

$$A > 3 B \qquad ( II )$$

FIG. 6 is a cross-sectional view illustrating a state after a dry desmear treatment is performed on the insulating layer 14 in which the through hole 18 is formed. As illustrated in FIG. 5, the inorganic fillers 12 may be exposed on the side surface of the through hole 18 formed in the insulating layer 14 by the laser processing or the like. A state in which the metal protective film 16 is provided on the surface of the insulating layer 14 is maintained at a portion other than the portion where the through hole 18 is formed in the insulating layer 14. Since the metal protective film 16 has resistance to the dry desmear treatment, when the insulating layer 14 is subject to the dry desmear treatment, the side surface of the through hole 18 is intensively treated, and the unevenness on the side surface of the through hole 18 caused by the inorganic fillers 12 is reduced.

Examples of the dry desmear treatment include a desmear treatment using plasma. In another example, as the dry desmear treatment, dry sand blasting treatment that can polish a treatment target by spraying an abrasive material from a nozzle may be used. Among them, the desmear treatment using plasma, which is excellent in removability of the inorganic filler 12, is preferable.

Examples of gas species in the case of performing the desmear treatment using plasma include O₂, CF₄, C₂F₄, C₃F₈, NF₃, H₂, Ar, N₂, and mixed gases thereof. An ambient pressure at the time of performing the desmear treatment using plasma is preferably 200 Pa or less, more preferably 150 Pa or less, and still more preferably 100 Pa or less. The treatment time at the time of performing the desmear treatment using plasma is preferably from 0.5 minutes to 30.0 minutes, and more preferably from 1.0 minutes to 10.0 minutes.

The dry desmear treatment is preferably performed until an average height C of protrusions derived from the inorganic fillers 12 on the surface of the through hole 18 and the average maximum particle length B of the inorganic fillers 12 satisfy the following Relational Expression (I). By performing the dry desmear treatment until B and C satisfy the following Relational Expression (I), the occurrence of the unevenness on the side surface of the through hole 18 is further suppressed. The ratio (B/C) of the average maximum particle length B to the average height C of the protrusions is preferably from 2.1 to 4.0, more preferably from 2.3 to 3.5, and still more preferably from 2.5 to 3.0.

$$B > 2 C \qquad ( I )$$

At least one of a wet desmear treatment or a plasma ashing treatment may be further performed before the dry desmear treatment. By performing at least one of the wet desmear treatment or the plasma ashing treatment before the dry desmear treatment, a smear derived from the resin component generated at the time of forming the through hole 18 can be efficiently removed, and the bonding strength of the wiring layer formed in the through hole 18 to the insulating layer 14 can be improved.

Examples of the wet desmear treatment include a method including subjecting the insulating layer 14 to a swelling treatment, oxidatively decomposing smears with an alkaline permanganate solution or a chromate solution, and then performing a neutralization treatment and a water washing treatment.

Examples of the plasma ashing treatment include the desmear treatment using plasma described above.

After the dry desmear treatment is performed, a wiring layer is formed on the insulating layer 14. The wiring layer can be formed by a method of forming a metal pattern known in the field of a printed wiring board, such as a subtractive method or a semi-additive method.

When the wiring layer is formed on the insulating layer 14, the wiring layer may be formed after the metal protective film 16 is removed, or the wiring layer may be formed on the metal protective film 16 by the above-described method. When the wiring layer is formed on the metal protective film 16, the metal protective film 16 forms a part of the wiring layer. By forming the wiring layer on the insulating layer 14, the wiring layer is also formed on the side surface of the through hole 18. The wiring layer on the side surface of the through hole 18 functions as a conductor present in the through hole 18.

Examples of the metal which forms the wiring layer include copper, titanium, silver, gold, and alloys thereof.

By repeating the formation of the insulating layer 14 and the wiring layer, the multilayer wiring is formed in which wiring layers that are adjacent to each other via an insulating layer 14 are electrically connected to each other via the conductor in the through hole 18.

In FIG. 3, the insulating layer 14 having the metal protective film 16 on the surface thereof may be provided on the semiconductor substrate 10 by using a metal foil-attached adhesive film including an epoxy resin composition layer and a metal foil in this order. By bringing the epoxy resin composition layer in the metal foil-attached adhesive film into contact with the semiconductor substrate 10 and then curing the epoxy resin composition layer, the insulating layer 14 having the metal protective film 16 on the surface thereof can be provided on the semiconductor substrate 10.

As the metal foil-attached adhesive film, a metal foil-attached adhesive film in which the epoxy resin composition layer is formed on a metal foil as the support can be used. The details of the metal foil and the epoxy resin composition which forms the metal foil-attached adhesive film and the method of forming the epoxy resin composition layer are as described above.

In FIG. 4, the metal protective film 16 is partially removed in advance in the region Q. However, the region Q is not necessarily formed when a laser processing method which can form the through hole 18 in the insulating layer 14 in a state in which the metal protective film 16 is present is selected as a method of forming the through hole 18.

As illustrated in FIG. 6, a height C of the protrusion derived from the inorganic filler 12 refers to a height of the inorganic filler 12 protruding from the side surface of the through hole 18 from the side surface of the through hole 18 in the cross section of the through hole 18.

Regarding an average height C of the protrusions derived from the inorganic fillers 12, the heights C of the protrusions derived from the inorganic fillers 12 in each cross-sectional photograph are obtained for five cross-sectional photographs of the through hole 18, and an arithmetic average of the heights C of the top three portions (the heights C of 15 portions in total) is taken as the average height C of the protrusions derived from the inorganic fillers 12.

Regarding the average maximum particle length B of the inorganic fillers, the particle lengths B of the inorganic fillers 12 in each cross-sectional photograph are obtained for five cross-sectional photographs of the through hole 18, and an arithmetic average of the particle lengths B of the top three inorganic fillers 12 (total 15 particle lengths B) is taken as the average maximum particle length B of the inorganic fillers.

The average maximum particle length B of the inorganic fillers is preferably from 1 μm to 50 μm, more preferably from 1 μm to 30 μm, and still more preferably from 5 μm to 10 μm.

### Method of Manufacturing Printed Wiring Board

The method of manufacturing a semiconductor device of the disclosure can also be applied to manufacturing of a printed wiring board. That is, the method of manufacturing a printed wiring board of the disclosure is a method of manufacturing a printed wiring board including the multilayer wiring in which the wiring layers and the insulating layers are alternately layered, in which wiring layers that are adjacent to each other, in a layered direction, via an insulating layer are electrically connected to each other via the conductor present in the through hole provided in the insulating layer, and the multilayer wiring is formed by the steps of, providing the insulating layer having the metal protective film on the surface thereof and containing inorganic fillers having the average maximum particle length B of from 1 μm to 100 μm on the base; forming the through hole in the insulating layer, and performing the dry desmear treatment on the insulating layer in which the through hole is formed.

In the method of manufacturing a printed wiring board of the disclosure, for example, the printed wiring board as the multilayer wiring board can be obtained by forming the multilayer wiring in the same manner except that the semiconductor substrate 10 in FIG. 1 is changed to a core substrate. Examples of the core substrate include a glass epoxy substrate such as an FR-4 substrate, a polyester substrate, a polyimide substrate, a BT resin substrate, and a polyphenylene ether substrate.

### Semiconductor Device

The semiconductor device of the disclosure includes a semiconductor element and a multilayer wiring in which wiring layers electrically connected to the semiconductor element and insulating layers are alternately layered, in which wiring layers that are adjacent to each other, in the layered direction, via an insulating layer are electrically connected to each other via the conductor present in the through hole provided in the insulating layer, the insulating layer contains the inorganic fillers having the average maximum particle length B of from 1 μm to 100 μm, and the following Relational Expressions (I) and (II) are satisfied where C is the average height of the protrusions derived from the inorganic fillers on the side surface of the through hole and A is the average diameter of the through hole.

$$B > 2 C \qquad ( I )$$

$$A > 3 B \qquad ( II )$$

Since the semiconductor device of the disclosure satisfies Relational Expressions (I) and (II), the occurrence of unevenness on the side surface of the through hole is suppressed. As a result, the bonding strength of the conductor present in the through hole to the insulating layer is secured, and the reliability of the multilayer wiring tends to be improved.

A method of forming the multilayer wiring included in the semiconductor device is not particularly limited, and the multilayer wiring may be formed by the method of manufacturing a semiconductor device of the disclosure.

### EXAMPLES

Hereinafter, the disclosure will be specifically described with reference to examples, but the scope of the disclosure is not limited to these examples.

### Example 1

### Formation of Insulating Layer

An insulating layer, that is a cured product of an epoxy resin composition (containing 76% by volume of silica particles having a volume average particle diameter of 5.7 μm as inorganic fillers), was formed on a surface of a substrate on a side where a copper wiring was formed by using a compression molding device (CMP-1000 manufactured by TOWA CORPORATION) under conditions of a load of 3 MPa, a pressurization time of 600 seconds, a temperature of 150° C., and an average molding thickness of 0.1 mm, in which the substrate having the copper wiring on a surface thereof was obtained from a copper-clad laminated plate (MCL-E-679FG manufactured by Showa Denko Materials Co., Ltd.) having a base material thickness of 0.81 mm and a copper thickness of 18 μm. The average maximum particle length B of the inorganic fillers in the insulating layer was 23 μm.

### Formation of Metal Protective Film

The surface of the insulating layer obtained above was roughened by the wet desmear treatment. Surface roughness Ra of the roughened insulating layer was measured in accordance with JIS B0601: 2013 by using a contact type step profiler (DektakXT manufactured by Bruker), and the result was 0.32 μm.

Titanium and copper were deposited in this order on the insulating layer, which was subjected to the roughening treatment, under conditions to form a metal protective film with a titanium thickness of 25 nm and a copper thickness of 150 nm using a sputtering apparatus (SIC-500 manufactured by ULVAC, Inc.).

### [Partial Removal of Metal Protective Film] GNP-20998

A dry film resist (RD-1215 manufactured by Showa Denko Materials Co., Ltd.) was laminated on a surface of the metal protective film provided on the insulating layer by using a vacuum laminator (CV-300 manufactured by Nikko-Materials Co., Ltd.) under conditions of a load of 0.5 MPa and a temperature of 60° C. Subsequently, exposure was performed using a photomask and a UV exposure machine (ML-320 manufactured by Mikasa Co., Ltd.), and development was performed with 1% by mass sodium carbonate aqueous solution to form a pattern with a diameter of 0.15 mm corresponding to a region (region Q) corresponding to a portion where a through hole was to be provided. Thereafter, the portion of the metal protective film corresponding to the region Q was removed using a seed etching solution (WLC-C2 manufactured by MITSUBISHI GAS CHEMICAL COMPANY, INC.). Thereafter, the dry film resist was removed using a remover solution (R-100S and R-100 manufactured by MITSUBISHI GAS CHEMICAL COMPANY, INC.) to obtain an insulating layer which has a metal protective film on its surface, in which the metal protective film includes the region Q of with a diameter of 0.15 mm formed thereon.

### Formation of Through Hole

A through hole was formed, on a portion where the region Q was formed, by performing laser processing with a CO₂ laser processing machine under a condition to provide the through hole which has a diameter of 0.15 mm, penetrates the insulating layer, and did not penetrate the copper wiring on the copper-clad laminated plate. An average diameter A of the through hole was 132 μm.

### Dry Desmearing

The dry desmear treatment was performed on the insulating layer in which the through hole was formed under the condition that the following Relational Expression (I) was satisfied provided that a surface of the inorganic filler contained in the insulating layer was scraped where B is an average of the maximum particle length of the inorganic fillers and Cis an average height of protrusions derived from the inorganic fillers on a side surface of the through hole. As the dry desmear treatment, a desmear treatment using plasma of CF₄ was adopted.

$$B > 2 C \qquad ( I )$$

### Formation of Wiring Layer

After the dry smearing, wiring formation was performed on the insulating layer having the through hole by using a semi-additive (SAP) method to connect the wiring on the insulating layer and the copper wiring on the base material to each other. In the obtained multilayer wiring, the average height C of the protrusions derived from the inorganic fillers on the side surface of the through hole was 8 μm.

### Comparative Example 1

The wiring on the insulating layer and the copper wiring on the base material were connected to each other in the same manner as in Example 1 except that [Formation of Metal Protective Film] and [Partial Removal of Metal Protective Film] were not performed. In the obtained multilayer wiring, the average height C of the protrusions derived from the inorganic fillers on the side surface of the through hole was 17 μm.

All documents, patent applications, and technical standards described in the present disclosure are herein incorporated by reference to the same extent as if each individual document, patent application, or technical standard was specifically and individually indicated to be incorporated by reference.

### DESCRIPTION OF REFERENCE NUMERALS

### Description of Signs

10: Semiconductor substrate
12: Filler
14: Insulating layer
16: Protective film
18: Through hole
Q: Region which corresponds to a portion where a through hole is to be provided

1. A method of manufacturing a semiconductor device comprising a multilayer wiring in which wiring layers and insulating layers are alternately layered,
wherein wiring layers that are adjacent to each other, in a layered direction, via an insulating layer are electrically connected to each other via a conductor present in a through hole provided in the insulating layer, and
the multilayer wiring is formed by:
providing, on a base, an insulating layer having a metal protective film on a surface thereof and containing inorganic fillers having an average maximum particle length B of from 1 μm to 100 μm;
forming a through hole in the insulating layer; and
subjecting, to a dry desmear treatment, the insulating layer in which the through hole is formed.

2. The method of manufacturing a semiconductor device according to claim 1, wherein the dry desmear treatment is performed until an average height C of protrusions derived from the inorganic fillers on a side surface of the through hole and an average maximum particle length B of the inorganic fillers satisfy the following Relational Expression (I),
$$B > 2 C . \qquad ( I )$$

3. The method of manufacturing a semiconductor device according to claim 1, wherein the following Relational Expression (II) is satisfied, wherein A is an average diameter of the through hole,
$$A > 3 B . \qquad ( II )$$

4. The method of manufacturing a semiconductor device according to claim 1, wherein the through hole is formed by at least one selected from the group consisting of laser processing and photolithography.

5. The method of manufacturing a semiconductor device according to claim 4, wherein the through hole is formed by removing, by the photolithography, a region corresponding to a portion at which the through hole is to be provided in the metal protective film, and then performing the laser processing on a portion from which the metal protective film is removed.

6. The method of manufacturing a semiconductor device according to claim 4, wherein the through hole is formed by performing the laser processing in a state in which the metal protective film is present on a surface of the insulating layer.

7. The method of manufacturing a semiconductor device according to claim 1, wherein the insulating layer having the metal protective film on the surface thereof is provided on the base by:
providing the insulating layer on the base;
roughening the surface of the insulating layer, and
disposing the metal protective film on the roughened surface of the insulating layer.

8. The method of manufacturing a semiconductor device according to claim 7, wherein the surface of the insulating layer is roughened by at least one selected from the group consisting of grinding, a chemical liquid treatment, and a plasma etching treatment.

9. The method of manufacturing a semiconductor device according to claim 7, wherein the metal protective film is formed by at least one selected from the group consisting of metal vapor deposition, electroless plating, and electrolytic plating.

10. The method of manufacturing a semiconductor device according to claim 7, wherein a surface roughness Ra of the roughened insulating layer is from 0.1 μm to 2.0 μm.

11. The method of manufacturing a semiconductor device according to claim 1, wherein the insulating layer is a cured product of an epoxy resin composition.

12. The method of manufacturing a semiconductor device according to claim 1, wherein the insulating layer having the metal protective film on the surface thereof is provided on the base by: bringing, into contact with the base, an epoxy resin composition layer in an adhesive film, wherein the adhesive film comprises the epoxy resin composition layer and a metal foil in this order; and then curing the epoxy resin composition layer.

13. The method of manufacturing a semiconductor device according to claim 1, further comprising forming a wiring layer on the insulating layer that has been treated by the dry desmear treatment.

14. The method of manufacturing a semiconductor device according to claim 13, wherein the wiring layer is formed after the metal protective film is removed from a surface of the insulating layer.

15. The method of manufacturing a semiconductor device according to claim 13, wherein the wiring layer is formed on the metal protective film.

16. The method of manufacturing a semiconductor device according to claim 1, further comprising performing, before the dry desmear treatment, at least one of a wet desmear treatment and a plasma ashing treatment.

17. A semiconductor device, comprising:
a semiconductor element; and
a multilayer wiring in which wiring layers electrically connected to the semiconductor element, and insulating layers, are alternately layered,
wherein:
wiring layers that are adjacent to each other, in a layered direction, via an insulating layer are electrically connected to each other via a conductor present in a through hole provided in the insulating layer;
the insulating layer comprises inorganic fillers having an average maximum particle length B of from 1 μm to 100 μm; and
the following Relational Expressions (I) and (II) are satisfied, wherein C is an average height of protrusions derived from the inorganic fillers on a side surface of the through hole and A is an average diameter of the through hole,
$$B > 2 C , and \qquad ( I )$$
$$A > 3 B . \qquad ( II )$$
